(19) United States
(12) Patent Application Publication
(10) Pub. No.: US 2023/0152383 A1
(43) Pub. Date: May 18, 2023

(54) SYSTEM AND METHOD WITH BATTERY MANAGEMENT

(71) Applicant: Samsung Electronics Co., Ltd., Suwon-si (KR)

(72) Inventors: Sagar BHARATHRAJ, Bangalore (IN); Myeongjae LEE, Seoul (KR); Shashishekara Parampalli ADIGA, Bangalore (IN); Tae Won SONG, Yongin-si (KR); Young Hun SUNG, Hwaseong-si (KR)

(73) Assignee: Samsung Electronics Co., Ltd., Suwon-si (KR)

(21) Appl. No.: 17/950,426

(22) Filed: Sep. 22, 2022

(30) Foreign Application Priority Data
Nov. 12, 2021 (IN) 202141052058
Apr. 14, 2022 (KR) 10-2022-0046433

(51) Int. Cl. G01R 31/389; H02J 7/00; G01R 31/396; G01R 31/3842

(52) U.S. Cl. CPC G01R 31/389; H02J 7/0047; G01R 31/396; G01R 31/3842

(57) ABSTRACT

A processor-implemented method of a battery management system includes: determining one or more pieces of sampling data from a plurality of pieces of battery usage data of a battery; determining a first short fatigue metric (SFM) score based on the determined one or more pieces of sampling data; and storing the first SFM score, wherein the one or more pieces of sampling data comprises any one or any combination of any two or more of: a high charging profile associated with the battery; a high discharging profile associated with the battery; a partial charging profile associated with the battery; and a partial discharging profile associated with the battery.

### CROSS-REFERENCE TO RELATED APPLICATIONS

This application claims the benefit under 35 USC § 119(a) of Indian Patent Application No. 202141052058, filed on Nov. 12, 2021 with the Indian Patent Office, and Korean Patent Application No. 10-2022-0046433, filed on Apr. 14, 2022 with the Korean Intellectual Property Office, the entire disclosures of which are incorporated herein by reference for all purposes.

BACKGROUND

### 1. Field

The following description relates to a system and method with battery management.

### 2. Description of Related Art

A typical method may accurately detect only an advanced stage of a short circuit of a battery, which may be too late for taking any prudent corrective action on the battery. In addition, the typical method may require a specialized battery feature and more data associated with the battery to perform a corrective action on the battery. This may lead to an inconvenient user experience.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a processor-implemented method of a battery management system includes: determining one or more pieces of sampling data from a plurality of pieces of battery usage data of a battery; determining a first short fatigue metric (SFM) score based on the determined one or more pieces of sampling data; and storing the first SFM score, wherein the one or more pieces of sampling data comprises any one or any combination of any two or more of: a high charging profile associated with the battery; a high discharging profile associated with the battery; a partial charging profile associated with the battery; and a partial discharging profile associated with the battery.

The method may include: determining an SFM and short circuit detection and estimation module based on the determined one or more pieces of sampling data; determining a first resistance value using the SFM and short circuit detection and estimation module; and determining a second SFM score based on the determined first resistance value and the determined first SFM score, wherein the first resistance value is determined using a short circuit-reduced order model (SC-ROM) module of the SFM and short circuit detection and estimation module, and wherein the SC-ROM module corresponds a physics-based electrochemical-thermal model comprising charge balance data of the battery to determine an effect of short circuit of the battery.

The method may include: re-determining the first resistance value based on the second SFM score using the SC-ROM module; determining a second resistance value using the SC-ROM module; and determining an output short resistance based on the re-determined first resistance value and the determined second resistance value.

The determining of the second SFM score may include determining the second SFM score based on any one or any combination of any two or more of a voltage hysteresis ratio, an energy hysteresis ratio, and a charge/discharge energy hysteresis ratio.

The first SFM score may be a sum of a capacity ratio and an energy ratio of a short circuit cell of the battery.

The second SFM score may be a relative change between a sum of a capacity ratio and an energy ratio of a normal cell of the battery and the sum of the capacity ratio and the energy ratio of the short circuit cell of the battery.

The method may include predicting either one or both of a temperature profile associated with the battery and a voltage profile associated with the battery, based on a final short resistance.

The SFM and short circuit detection and estimation module may determine a change of one or more parameters associated with the battery, and the one or more parameters may include any one or any combination of any two or more of a concentration, a state of charge, a voltage, and a temperature of the battery.

The method may include estimating a short circuit and a short resistance in either one or both of a cell of the battery and a battery pack of the battery, based on the determined first SFM score.

The SFM and short circuit detection and estimation module may estimate either one or both of a short circuit of the battery and a short resistance of the battery.

The battery management system may be included in any one or any combination of any two or more of a hybrid car, an electric vehicle, and an electronic device comprising the battery.

The plurality of pieces of battery usage data may include any one or any combination of any two or more of an initial voltage, a total current profile, current state information, and an initial temperature.

The first resistance value may be determined by a predetermined first resolution, and the second resistance value may be determined by a resolution more precise than the first resolution around the first resistance value.

In another general aspect, one or more embodiments include a non-transitory computer-readable storage medium storing instructions that, when executed by one or more processors, configure the one or more processors to perform any one, any combination, or all operations and methods described herein.

In another general aspect, a battery management system includes: a battery management controller configured to: determine one or more pieces of sampling data from a plurality of pieces of battery usage data of a battery; determine a first short fatigue metric (SFM) score based on the determined one or more pieces of sampling data; and store the first SFM score in the battery management system, and wherein the one or more pieces of sampling data may include any one or any combination of any two or more of: a high charging profile associated with the battery; a high discharging profile associated with the battery; a partial charging profile associated with the battery; and a partial discharging profile associated with the battery.

The battery management controller may be configured to: determine an SFM and short circuit detection and estimation module based on the determined one or more pieces of sampling data, determine a first resistance value using the SFM and short circuit detection and estimation module, and determine a second SFM score based on the determined first resistance value and the determined first SFM score, wherein the first resistance value may be determined using a short circuit-reduced order model (SC-ROM) module of the SFM and short circuit detection and estimation module, and wherein the SC-ROM module may correspond a physics-based electrochemical-thermal model comprising charge balance data of the battery to determine an effect of short circuit of the battery.

The battery management controller may be configured to: re-determine the first resistance value based on the second SFM score by using the SC-ROM module; determine a second resistance value using the SC-ROM module; and determine an output short resistance based on the re-determined first resistance value and the determined second resistance value.

The first SFM score may be a sum of a capacity ratio and an energy ratio of a short circuit cell of the battery.

The battery management controller may be configured to predict either one or both of a temperature profile associated with the battery and a voltage profile associated with the battery, based on a final short resistance.

The SFM and short circuit detection and estimation module may determine a change of one or more parameters associated with the battery, and the one or more parameters may include any one or any combination of any two or more of a concentration, a state of charge, a voltage, and a temperature of the battery.

The SFM and short circuit detection and estimation module may estimate either one or both of a short circuit of the battery and a short resistance of the battery.

The battery management controller may include one or more processors, and the battery management controller may include a memory storing instructions that, when executed by the one or more processors, configure the one or more processors to perform the determining of the one or more pieces of sampling data, the determining of the first SFM score, and the storing of the first SFM score.

In another general aspect, a processor-implemented method of a battery management system includes: determining, based on a plurality of pieces of battery usage data of a battery, one or more pieces of sampling data comprising either one or both of a charging profile and a discharging profile of the battery; determining a first short fatigue metric (SFM) score based on the determined one or more pieces of sampling data; determining an SFM and short circuit detection and estimation module based on the determined one or more pieces of sampling data; determining a first resistance value using the SFM and short circuit detection and estimation module; and determining a second SFM score based on the determined first resistance value and the determined first SFM score.

Other features and aspects will be apparent from the following detailed description, the drawings, and the claims.

### BRIEF DESCRIPTION OF THE DRAWINGS

FIG. 1 is a diagram illustrating various hardware components of a battery management system according to one or more embodiments.

FIG. 2 is a diagram illustrating an overview of a system including a battery management system for estimating a short resistance and a short circuit of a battery of an electronic device according to one or more embodiments.

FIG. 3 is a diagram illustrating an overview of a system including a battery management system for estimating a short resistance and a short circuit of a battery of an electric vehicle or a hybrid vehicle according to one or more embodiments.

FIG. 4 is a flowchart of an example of a method of managing usage of a battery according to one or more embodiments.

FIGS. 5A and 5B are circuit diagrams illustrating an example of a short circuit including a short fatigue metric (SFM) according to one or more embodiments.

FIG. 6 is a graph illustrating an example of estimating a first resistance value using blind data according to one or more embodiments.

FIG. 7 is a graph illustrating an example of estimating a second resistance value using blind data according to one or more embodiments.

FIG. 8 is a graph illustrating an example of predicting a temperature of blind data according to one or more embodiments.

FIG. 9 is a graph illustrating an example of a match of voltage profiles between an output resistance and blind data.

FIG. 10 is a graph illustrating an example of accumulating short fatigue metric evaluation data described according to one or more embodiments.

Throughout the drawings and the detailed description, unless otherwise described or provided, the same drawing reference numerals will be understood to refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known, after an understanding of the disclosure of this application, may be omitted for increased clarity and conciseness.

The terminology used herein is for the purpose of describing one or more embodiments only and is not to be limiting of the one or more embodiments. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or combinations thereof. The use of the term “may” herein with respect to an example or embodiment (for example, as to what an example or embodiment may include or implement) means that at least one example or embodiment exists where such a feature is included or implemented, while all examples are not limited thereto.

Unless otherwise defined, all terms, including technical and scientific terms, used herein have the same meaning as commonly understood by one of ordinary skill in the art to which one or more embodiments pertain and based on an understanding of the disclosure of the present application. It will be further understood that terms, such as those defined in commonly-used dictionaries, should be interpreted as having a meaning that is consistent with their meaning in the context of the relevant art and the disclosure of the present application, and will not be interpreted in an idealized or overly formal sense unless expressly so defined herein.

When describing the one or more embodiments with reference to the accompanying drawings, like reference numerals refer to like constituent elements and a repeated description related thereto will be omitted. In the description of one or more embodiments, detailed description of well-known related structures or functions will be omitted when it is deemed that such description will cause ambiguous interpretation of the present disclosure.

Although terms, such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in the examples described herein may also be referred to as a second member, component, region, layer, or section without departing from the teachings of the examples.

Throughout the specification, when a component is described as being “connected to,” “coupled to,” or “accessed to” another component, it may be directly “connected to,” “coupled to,” or “accessed to” the other component, or there may be one or more other components intervening therebetween. In contrast, when an element is described as being “directly connected to,” “directly coupled to,” or “directly accessed to” another element, there can be no other elements intervening therebetween. Likewise, similar expressions, for example, “between” and “immediately between,” and “adjacent to” and “immediately adjacent to,” are also to be construed in the same way. As used herein, the term “and/or” includes any one and any combination of any two or more of the associated listed items.

The same name may be used to describe an element included in the one or more embodiments described above and an element having a common function. Unless otherwise mentioned, the descriptions on the one or more embodiments may be applicable to the following one or more embodiments and thus, duplicated descriptions will be omitted for conciseness.

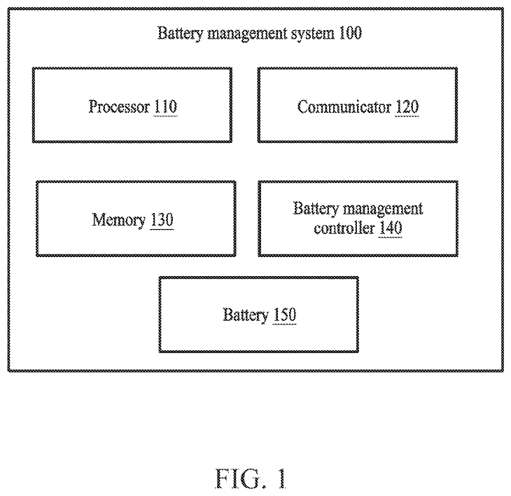

Hereinafter, with reference to FIGS. 1 to 10, one or more embodiments of a battery management system (e.g., a battery management apparatus) and a method of managing usage of a battery is described.

One or more embodiments of the present disclosure provide a method of managing usage of a battery. In an example, the method may include obtaining (e.g., generating or determining), by a battery management system, sampling data from a plurality of pieces of battery usage data. The sampling data may include a high charging profile associated with a battery, a high discharging profile associated with the battery, a partial charging profile associated with the battery, and/or a partial discharging profile associated with the battery. In addition, the method may include determining a first short fatigue metric (SFM) score based on the sampling data obtained by the battery management system. In addition, the method may include storing the first SFM score in the battery management system by the battery management system.

Unlike the typical method and system, the method of one or more embodiments may be used for detecting a short circuit (for example, a soft short circuit up to 500Ω) at an early stage with high accuracy by using normal use battery data. The method may be implemented in the battery management system without changing the existing protocol/hardware of the battery management system. In the method of one or more embodiments, an SFM score amplifying underlying short specific charge hysteresis and underlying short specific discharge hysteresis may be used as an identifying and differentiating criterion for a short circuit in an SFM model. The method of one or more embodiments may detect (up to 500Ω) an early short circuit with an accuracy of more than 99% within a short time (for example, three seconds) and may estimate a short resistance by executing a physics-based module (for example, a short circuit reduced order model (SC-ROM) module) in the background and analyzing user data (for example, up to 4 hours of data).

Referring to FIGS. 1 to 10, one or more embodiments with similar reference numerals denoting corresponding features consistently throughout the drawings are illustrated.

FIG. 1 is a diagram illustrating various hardware components of a battery management system 100 (e.g., a battery management apparatus) according to one or more embodiments. In one or more embodiments, the battery management system 100 may include a processor 110 (e.g., one or more processors), a communicator 120, a memory 130 (e.g., one or more memories), a battery management controller 140, and a battery 150. The processor 110 may be connected to the communicator 120, the memory 130, the battery management controller 140, and the battery 150. The battery 150 may be a lithium ion battery, a nickel cadmium battery, a magnesium-ion battery, a nickel metal hydride battery, and/or a small sealed lead acid battery. However, the example is not limited thereto. The battery management system 100 may perform any one, any combination, or all of the methods and operations described herein with reference to FIGS. 1-10.

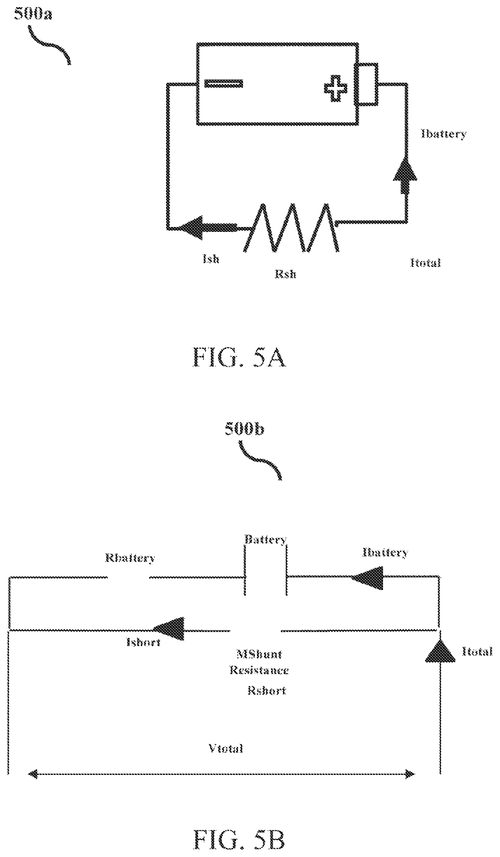

The battery management controller 140 may be configured to obtain sampling data from a plurality of pieces of battery usage data. The sampling data, for example, may be a high charging profile related to the battery 150, a high discharging profile related to the battery 150, a partial charging profile related to the battery 150, and/or a partial discharging profile related to the battery 150. However, the example is not limited thereto. The plurality of pieces of battery usage data may be, for example, an initial voltage, a total current profile, state of charge (SOC) information, and/or an initial temperature. However, the example is not limited thereto. Based on the obtained sampling data, the battery management controller 140 may be configured to determine a first SFM score and store the first SFM score in the battery management system 100. The first SFM score may be a sum of a capacity ratio (CR) of a short circuit cell of the battery 150 and an energy ratio (ER) of the short circuit cell. A non-limiting example of the sum of CR and ER of the short circuit cell of the battery 150 is described below with reference to FIG. 5.

In addition, the battery management controller 140 may be configured to determine an SFM and short circuit detection and estimation module (e.g., being or including a model) based on the obtained sampling data. The SFM and short circuit detection and estimation module may determine a change in a parameter related to the battery 150. The parameter, for example, may be a concentration, an SOC, a voltage, and/or a temperature. However, the example is not limited thereto. In addition, the SFM and short circuit detection and estimation module may estimate (e.g., determine) a short circuit and a short resistance of the battery 150. In addition, the battery management controller 140 may be configured to estimate a first resistance value (for example, a global resistance) by using the SFM and short circuit detection and estimation module. The first resistance value may be estimated using an SC-ROM module as or of the SFM and short circuit detection and estimation module. The SC-ROM module may correspond to a physics-based electrochemical-thermal model framework including charge balance data of the battery 150 to estimate an effect of a short circuit the battery 150. The first resistance value may be determined by searching for a high resolution of the resistance in the first resistance value.

Based on the estimated first resistance value and the determined first SFM score, the battery management controller 140 may be configured to determine a second SFM score. The second SFM score may be, or correspond to, a relative change or difference between a sum of CR and ER of a normal cell of the battery 150 and a sum of CR and ER of a short circuit cell of the battery 150. A non-limiting example of the relative change between the sum of CR and ER of the normal cell of the battery 150 and the sum of CR and ER of the short circuit cell of the battery 150 is described with reference to FIG. 5. The second SFM score may be determined based on a voltage hysteresis ratio, an energy hysteresis ratio, and/or a charge-discharge energy hysteresis ratio of the battery. In one or more embodiments, a search for a second resistance value may be performed around or near the first resistance value (e.g., within a range of values from the first resistance value) to estimate the second resistance value by a more precise resolution than a first resolution.

In addition, the battery management controller 140 may be configured to estimate (e.g., re-estimate) the first resistance value based on the second SFM score. The first resistance value may be estimated using the SC-ROM module. In addition, the battery management controller 140 may be configured to estimate the second resistance value (for example, a local resistance). The second resistance value may be estimated using the SC-ROM module. In addition, the battery management controller 140 may be configured to determine an output short resistance based on the estimated first resistance value and the estimated second resistance value.

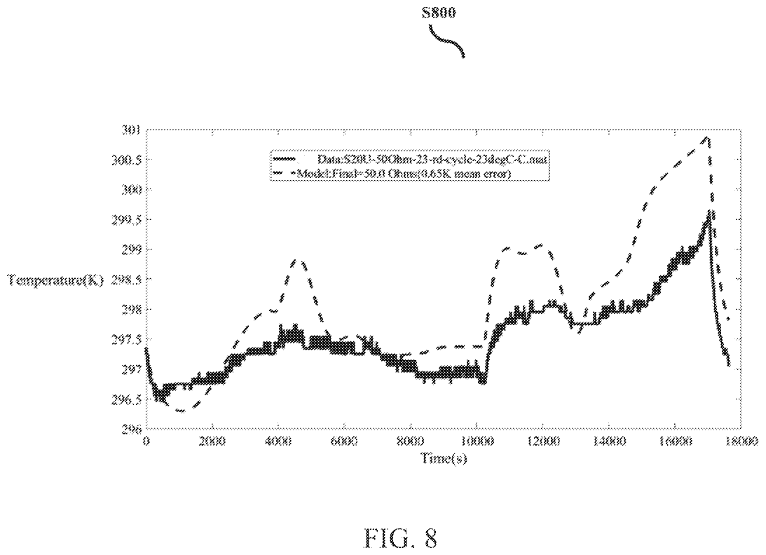

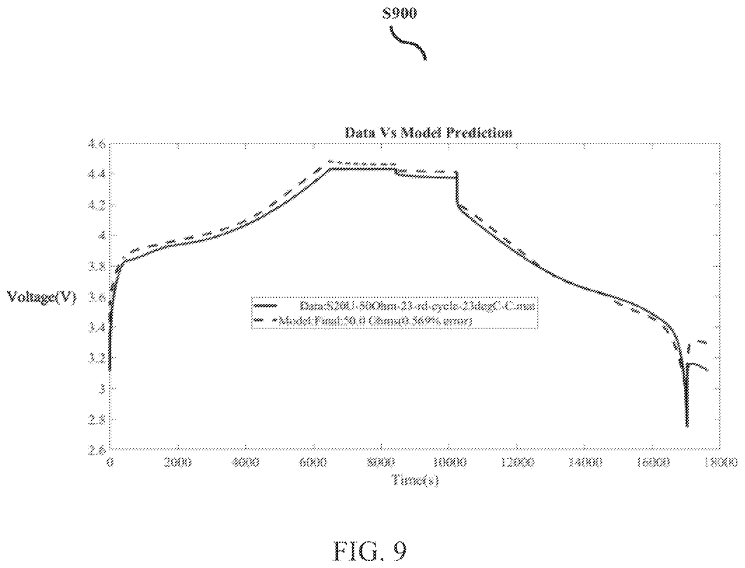

In addition, the battery management controller 140 may be configured to predict a temperature profile (e.g., a graph S800 shown in FIG. 8) associated with the battery 150 and a voltage profile (e.g., a graph S900 shown in FIG. 9) associated with the battery 150 based on a final short resistance.

The battery management controller 140 may be, or be physically implemented by, an analog or digital circuit, such as a logic gate, an integrated circuit, microprocessors, microcontrollers, a memory circuit, a passive electronic component, an active electronic component, an optical component, and/or a hardwired circuit, and may optionally be driven by firmware. In a non-limiting example. the battery management controller 140 may be or include one or more processors and/or may be or include the processor 110.

In addition, the processor 110 may be configured to execute instructions stored in the memory 130 and perform various processes. The instructions, when executed by the processor 110, may configure the processor 110 to perform the various processes. The communicator 120 may be configured to internally communicate between internal hardware components and an external device via one or more networks. The memory 130 may also store the instructions to be executed by the processor 110. The memory 130 may be a non-transitory computer-readable storage medium (e.g., including a non-volatile storage element) in which the instructions are stored. Examples of the non-transitory computer-readable storage medium may include a magnetic hard disc, an optical disc, a floppy disc, flash memory, electrically programmable memory (EPROM), and/or electrically erasable and programmable memory (EEPROM). The term “non-transitory” may indicate that the storage medium is not embodied in a carrier wave or a propagated signal. However, the term “non-transitory” should not be interpreted that the memory 130 is non-movable. In some examples, the non-transitory storage medium may store (for example, store in random access memory (RAM) or cache) data that may change over time.

In addition, at least one of a plurality of modules/controllers may be implemented through an artificial intelligence (AI) model using a data driven model controller (not shown). A function related to the AI model may be performed through a non-transitory computer-readable storage medium, a volatile memory, and the processor 110. The processor 110 may include one or a plurality of processors. In this case, the one or a plurality of processors may be a general purpose processor (e.g., such as a central processing unit (CPU) and/or an application processor (AP)), a graphics-only processing unit (e.g., such as a graphics processing unit (GPU) and/or a visual processing unit (VPU)), and/or an A1-dedicated processor (e.g., such as a neural processing unit (NPU)).

The one or a plurality of processors may control the processing of input data based on a predefined operation rule or the AI model stored in the non-transitory computer-readable storage medium memory and the volatile memory. The predefined operation rule or the AI model may be provided through training or learning.

Herein, providing of the predefined operation rule or the AI model through learning may indicate creating the predefined operation rule or the AI model with a desired characteristic by applying a learning algorithm to a plurality of pieces of training data. The training may be performed by a device in which the AI according to one or more embodiments is performed, and may be implemented by a separate server and/or system.

The AI model may include a plurality of neural network layers. Each layer may have a plurality of weight values and may perform a layer operation through calculation of a previous layer and a plurality of weight operations. Examples of the neural network may include a convolutional neural network (CNN), a deep neural network (DNN), a recurrent neural network (RNN), a restricted Boltzmann machine (RBM), a deep belief network (DBN), a bidirectional recurrent deep neural network (BRDNN), a generative adversarial network (GAN), and/or a deep Q-network. However, examples are not limited thereto.

The learning algorithm may be a method of training a predetermined target device (for example, a robot) using a plurality of pieces of training data to cause, allow, or control the target device to perform determination or prediction. Examples of the learning algorithm may include, but are not limited to, supervised learning, unsupervised learning, semi-supervised learning, and/or reinforcement learning.

Although FIG. 1 illustrates various hardware components of the battery management system 100, it should be understood that other one or more embodiments are not limited thereto. In other one or more embodiments, the battery management system 100 may include less or more components. Furthermore, the labels or names of the components are used only for illustrative purpose and do not limit the scope of the present disclosure. One or more components may be coupled to perform the same or a substantially similar function in the battery management system 100.

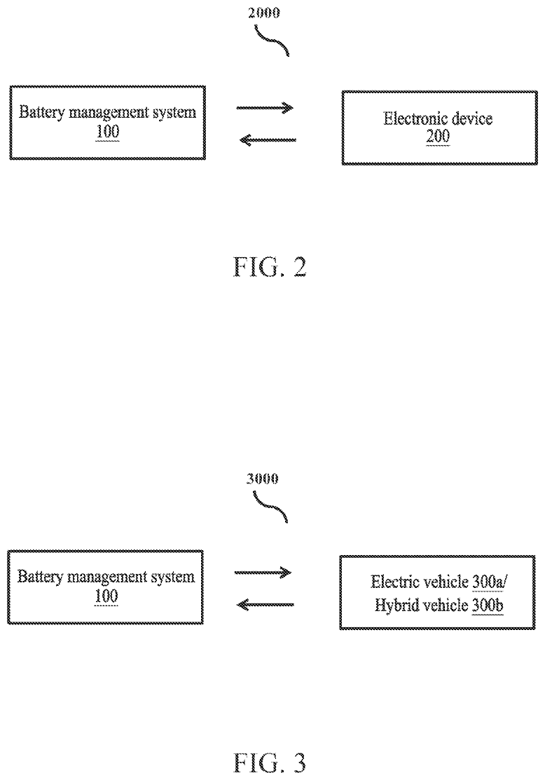

FIG. 2 is a diagram illustrating an overview of a system 2000 including the battery management system 100 for estimating a short circuit of the battery 150 and a short resistance of the battery 150 of an electronic device 200 according to one or more embodiments. The operation and function of the battery management system 100 have been already described with reference to FIG. 1. The electronic device 200 may be, for example, a smartphone, a laptop, a tablet, an immersive device, a virtual reality device, a foldable device, and an Internet of Things (IoT) device. However, examples are not limited thereto.

FIG. 3 is a diagram illustrating an overview of a system 3000 including the battery management system 100 for estimating a short circuit in the battery 150 and a short resistance of the battery 150 of an electric vehicle 300a or a hybrid vehicle 300b according to one or more embodiments. Operations and function of the battery management system 100 has been already described with reference to FIG. 1, and such operations and functions are incorporated herein by reference.

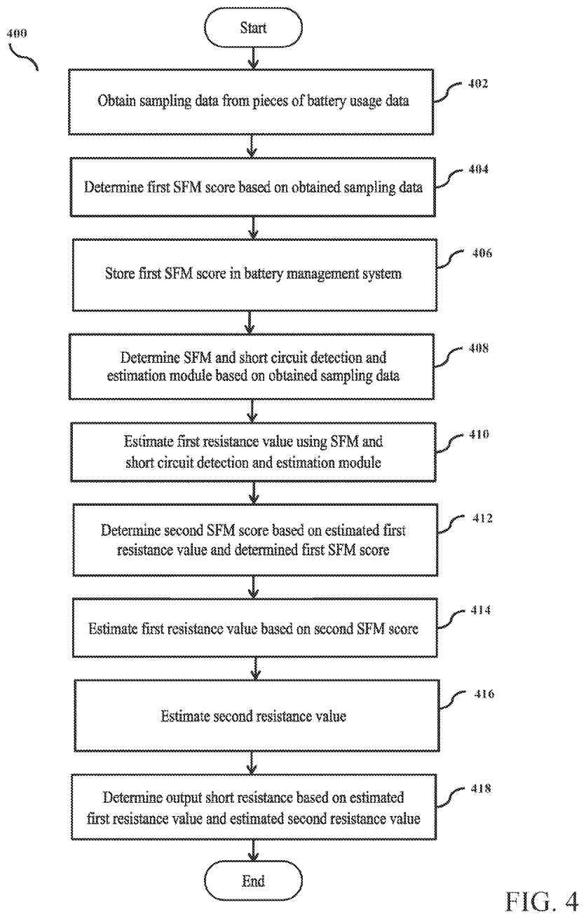

FIG. 4 is a flowchart 400 of an example of a method of managing usage of the battery 150 according to one or more embodiments. Operations 402 to 418 may be performed by the battery management controller 140. The operations in FIG. 4 may be performed in the sequence and manner as shown. However, the order of some operations may be changed, or some of the operations may be omitted, without departing from the spirit and scope of the shown example. Additionally, operations illustrated in FIG. 4 may be performed in parallel or simultaneously. One or more blocks of FIG. 4, and combinations of the blocks, can be implemented by special purpose hardware-based computer that perform the specified functions, or combinations of special purpose hardware and instructions, e.g., computer or processor instructions. In addition to the description of FIG. 4 below, the descriptions of FIGS. 1-3 are also applicable to FIG. 4 and are incorporated herein by reference. Thus, the above description may not be repeated here for brevity purposes.

In operation 402, the method may include obtaining sampling data from a plurality of pieces of battery usage data. In operation 404, the method may include determining a first SFM score based on the obtained sampling data. In operation 406, the method may include storing the first SFM score in the battery management system 100. In operation 408, the method may include determining an SFM and short circuit detection and estimation module based on the obtained sampling data.

In operation 410, the method may include estimating a first resistance value by using the SFM and short circuit detection and estimation module. In operation 412, the method may include determining a second SFM score based on the estimated first resistance value and the determined first SFM score. In operation 414, the method may include estimating (e.g., re-estimating) the first resistance value based on the second SFM score. In operation 416, the method may include estimating the second resistance value. In operation 418, the method may include determining an output short resistance based on the estimated first resistance value and the estimated second resistance value.

Unlike the typical method and system, the method of one or more embodiments may be used for detecting a short circuit (for example, a soft short circuit up to 500Ω) at an early stage with high accuracy using normal usage battery data. The method may be implemented in the battery management system 100 without any change in the existing protocol/hardware on the battery management system 100. In the method of one or more embodiments, the SFM score amplifying an underlying short specific charge hysteresis and an underlying short specific discharge hysteresis may be used as a short circuit identifying and differentiating criterion in the SFM model. The method of one or more embodiments may detect (up to 500Ω) an early short circuit with an accuracy of more than 99% within a short time (for example, three seconds) by executing a physical-based module (for example, the SC-ROM module) in the background and analyzing user data (for example, up to 4 hours of data) and may estimate a short resistance.

FIGS. 5A and 5B are circuit diagrams 500a and 500b illustrating examples for describing a short circuit including an SFM. As shown in FIG. 5A, a short circuit may be characterized by an additional path for a current flow apart from the battery 150. Thus, a leakage/accumulation current associated with the short circuit may be included in discharge/charge modes as a part of a charge balance equation. For the model, the short circuit may be modeled as a shunt resistor of resistance Rₛₕ connected to a terminal or terminals of the battery 150, as shown in the circuit diagram of FIG. 5. Accordingly, the total current of the battery 150 of the battery management system 100 may be modified as Equation 1 below, for example.

Referring to FIG. 5B, a short circuit detection module may be integrated in an existing thermal reduced order model (T-ROM) framework. An additional short circuit module may include operations to modify the current balance including the short circuit. As shown in FIG. 5, the short circuit may be modeled as one resistance parallel with the battery 150. The equations leading to a change in the total charge balance is shown in Equations 1 to 3 below, for example.

Iₜₒₜₐₗ=I_{battery}+Iₛₕₒᵣₜ Equation 1

Vₜₒₜₐₗ=VOCV+R_{battery}*I_{battery}=Iₛₕₒᵣₜ*Rₛₕₒᵣₜ Equation 2

Iₜₒₜₐₗ may denote the total current, I_{battery} may denote an actually applied/battery current, and Iₛₕ may denote the current through the short circuit that is modeled as Equation 3 shown below, for example.

iₛₕₒᵣₜ=Vₜₒₜₐₗ/Rₛₕₒᵣₜ Equation 3

V_{cell} may denote a cell voltage and Rₛₕ may denote a shunt resistance.

This may lead to an overall influence on a battery state, such as concentration, SOC, voltage, and temperature, which may be small at the early stage of a short circuit. The SFM may assist to detect and estimate the short circuit and the short resistance (Rₛₕ/SOS) by capturing a small change and amplifying the change.

A short circuit module including an optimization routine to estimate a short circuit integrated with the T-ROM framework may be collectively referred to as the SC-ROM. An influence of a short circuit induced leakage current on the battery may be significant. For example, a system may discharge faster due to an additional path of lower resistance in a form of the shunt while discharging. While charging, since a portion of charging current is absorbed by the shunt, a charging speed may reversely decrease, specifically in a constant voltage (CV) phase of CCCV charging.

For example, by any chance, when a CV phase cut-off current (for example, Icut-off, which is typically at 10% of 1C CC current) is close to the shunt/short current (Iₛₕ, an end of the CV phase in the battery management system 100 may not be observed. For example, in case the 1 C CC current is 4.85 A (thus, Icut-off=0.485 A) and the CV phase is at 4.4 V, a short resistance of 8Ω may be Ish=4.4VΩ=0.55 A, that is, greater than Icut-off. Thus, the CV phase may never end due to an incessant shunt current requirement. Some of these signals may be limited to the short circuit in the late soft/early hard stage (for example, 20Ω<Rₛₕ<50Ω), compared to a normal cell.

For example, due to the short circuit, currents may accumulate during charging and a leakage of current may occur during discharging. Thus, in the early stage of the short circuit, the capacity (for example, coulomb counting) accumulation (charge) and depletion (discharge) may be individually negligible, compared to a normal cell. However, when comparing a ratio of accumulation to depletion with sufficient sampling time/SOC window, an attribute of the normal cell may be a remarkable attribute. Similar is the case for a change in energy (voltage×current) of the battery management system 100 for a charge and discharge cycle. The amount (for example, energy and capacity) may reflect the “hysteresis” of the system. The “fatigue” due to the hysteresis induced by the short circuit may be referred to as SFM. The SFM may include two main components in the form of a capacity ratio (C.R) and an energy ratio (E.R) defined by Equations 4 through 7 below, for example.

$$E . R = \frac{\int {V}_{Discharge} {I}_{Discharge} dt}{\int {V}_{Charge} {I}_{Charge} dt} \qquad Equation 4$$

$$C . R = \frac{\int {I}_{Discharge} dt}{\int {I}_{Charge} dt} \qquad Equation 5$$

$$S . F . M = {[ C . R + E … R ]}_{test cell} \qquad Equation 6$$

$$Relative S . F . M = 1 - ( \frac{{[ C . R . + E … R ]}_{test cell}}{{[ C . R + E … R ]}_{healthy cell}} ) \qquad Equation 7$$

S.F.M may denote a sum of C.R and E.R, as shown in Equation 6, relative S.F.M may denote a relative change between a sum of CR and ER of a short circuit cell and a sum of CR and ER of a normal cell, as shown in Equation 7. Herein, the short circuit cell may be interchangeably referred to as a test cell and the normal cell may be interchangeably referred to as a healthy cell.

When a blind data set (for example, unknown short resistance) is provided to an SD-TROM framework, “0” may be set and a short resistance value Rₛₕ may be estimated. An SFM value generated by the model for a different value of Rₛₕ may be compared to an SFM score of actual data. The Rₛₕ value of which an error between the actual data SFM (SFM _{data}) and the model SFM (SFM _{model}) is minimum may be chosen as a model predicted Rₛₕ. Since the model is to accurately predict a battery state, such as a voltage and a temperature, as well as to minimize an SFM error for predicting a correct short resistance, the model may be included in an objective statement. An assigned weight may be more biased to minimize the SFM error since the main objective of the assigned weight is to estimate a short resistance. Thus, a small optimization routine may be included in the SD-TROM framework with the objective statement.

Rₛₕ=min(0.75×|SFM_{data}−SFM_{model,R}_{ₛₕ}|+0.2 ×|V_{data}−V_{model,R}_{ₛₕ}|)/+0.05×|T_{data}−T_{model,R}_{ₛₕ}| Equation 8

In Equation 8 above, for example, while evaluating Rₛₕ, the optimization routine may perform a preliminary search with a greater Rₛₕ resolution/step size (for example, ΔRₛₕ=50Ω for Rₛₕ≤100Ω and ΔRₛₕ=100Ω for Rₛₕ>100Ω) to find an initial/first estimate of Rₛₕ. In addition, a local search may be performed around, or near, the initial Rₛₕ to estimate a final Rₛₕ with an accurate Rₛₕ value or more precise resolution/step size (a search window spanning ±25% of the initial Rₛₕ with a resolution of 2.5%×the initial Rₛₕ). The two-step search may be performed for a faster convergence to the final value. In addition, the initial Rₛₕ or the final Rₛₕ may be chosen as the estimate depending on the required level of detailing/coarse graining. When the predicted Rₛₕ (that is, initial or final) is greater than 600Ω, the cell may be considered as the normal cell. The optimization routine may complete the SD-TROM framework.

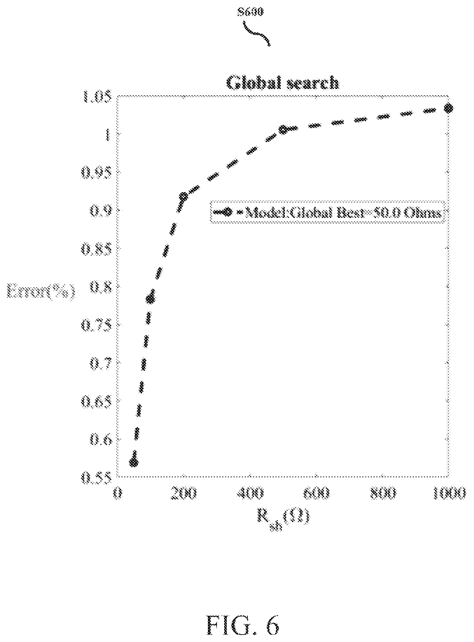

FIG. 6 is a graph S600 illustrating an example of estimating a first resistance value (that is, global resistance value estimation) using blind data.

Battery data used in the electronic device 200 (for example, a smartphone) may be generated under different conditions. The battery data under various operating conditions : ambient temperature 10° C. 23° C. 40° C., C-rate : Dynamic and Constant (Const). C-rate (0.1 C to 2 C rate) to emulate various user scenarios, fresh cycle and 50th cycle data, and a short resistance, Rₛₕ 50 Ω: 100 Ω: 200 Ω: 500Ω: ∞Ω (normal). Furthermore, about 25 data sets may be generated for various operating conditions. A blind data set may be provided to a module to estimate the global Rₛₕ and the local Rₛₕ for predicting the final Rₛₕ.

As shown in FIG. 6, the given blind data set (for example, the used blind data set : 23° C., Dynamic C-rate with 50Ω short resistance) and the model may search for a global resistance value of which a difference between an SFM value of the data and an SFM value of the model is minimum.

In this case, Rₛₕ=50Ω and the total prediction time may be less than 3 seconds in MATLAB.

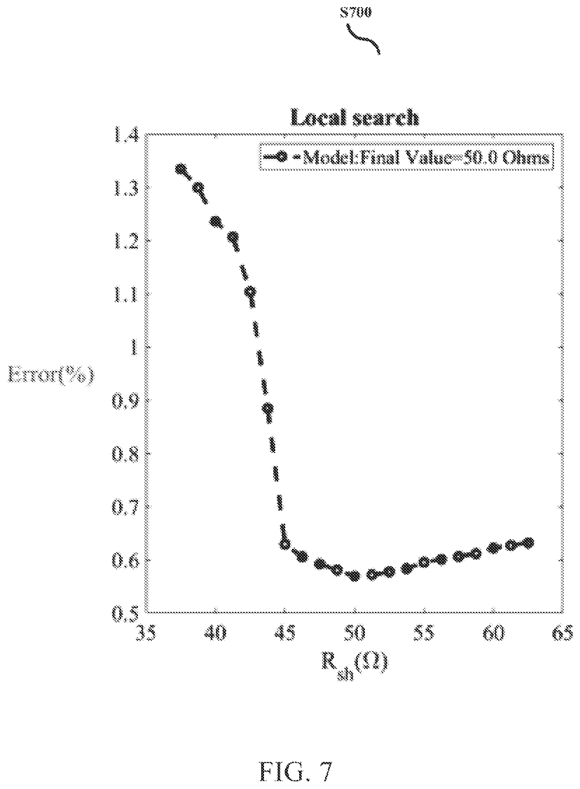

FIG. 7 is a graph S700 illustrating an example of estimating a second resistance value (that is, local resistance value estimation) using the blind data. As shown in FIG. 7, when a blind data set (for example, the used blind data set : 23° C., dynamic C-rate with 50Ω short resistance) is given, after the global search, a finer resolution may be performed around, or near, the global search for the accurate Rₛₕ value. Although 48.75Ω may have a minimum error, a difference in the SFM error between the global (50Ω=0.385%) and the local (48.75Ω=0.377%) may be less than 0.01%. Accordingly, in this case, the final value=the global value. Thus, the final Rₛₕ=50Ω and the SFM error may be less than 0.39%.

FIG. 8 is a graph S800 illustrating an example of predicting a temperature of blind data. As shown in FIG. 8, the model may include one input of an ambient temperature (or an initial temperature). A model predicted temperature profile and an experimental profile may have an excellent match in their features. According to the method of one or more embodiments, a mean temperature prediction error may be 0.54 K. FIG. 8 illustrates a comparison of temperatures between actual experimental data and a model prediction for a final value of a short resistance (50 ohms).

FIG. 9 is a graph S900 illustrating an example of a match of voltage profiles between an output resistance and blind data. With the predicted Rₛₕ (=50Ω) value, the voltage profile generated in the model may be compared to the voltage profile of the data. As shown, the model may capture all nuances of the voltage profile. FIG. 9 illustrates a comparison of voltages between the actual experimental data and the model prediction for the final value of the short resistance (for example, 50 ohms).

The method may be used for accurately predicting an output short resistance of the battery 150 of a smartphone at 23° C. For example, Table 1 may represent constant C-rate data and Table 2 may represent dynamic data.

TABLE 1

| Actual | Predicted | Predicted | Temp | |
|---|---|---|---|---|
| Rₛₕ (Ω) | Global (Ω) | Final (Ω) | Error | Error |
| ∞ | 1000 | 1000 (0.35%*) | 0.46 K\hat{ } | 0%⁺ |
| 500 | 500 | 500 (0.33%) | 0.49 K | 0% |
| 200 | 200 | 200 (0.35%) | 0.45 K | 0% |
| 100 | 100 | 100 (0.35%) | 0.94 K | 0% |
| 50 | 50 (0.34%) | 47.5 (0.31%) | 0.40 K | 5% |

*may represent an error between the model SFM and the data SFM (SFM_{data}), \hat{ }may represent a mean temperature difference between the model and the data, and ⁺may represent an error between experimental Rₛₕ and predicted Rₛₕ.

TABLE 2

| Actual | Predicted | Predicted | Temp | |
|---|---|---|---|---|
| Rₛₕ (Ω) | Global (Ω) | Final (Ω) | Error | Error |
| ∞ | 1000 | 1000 (0.43%) | 0.62 K | 0% |
| 500 | 500 | 500 (0.35%) | 0.57 K | 0% |
| 200 | 200 | 200 (0.38%) | 0.63 K | 0% |
| 100 | 100 | 100 (0.41%) | 0.61 K | 0% |
| 50 | 50 | 50 (0.38%) | 0.55 K | 0% |

The method may be used for accurately predicting an output short resistance of the battery 150 of a smartphone at various temperatures. Table 3 may represent constant C-rate data for a fresh cell at 10° C. and Table 4 may represent constant C-rate data for a fresh cell at 40° C.

TABLE 3

| Actual | Predicted | Predicted | Temp | |
|---|---|---|---|---|
| Rₛₕ (Ω) | Global (Ω) | Final (Ω) | Error | Error |
| ∞ | 1000 (0.59%) | 1100 (0.56%*) | 0.31 K\hat{ } | 10%⁺ |
| 500 | 500 | 500 (0.33%) | 0.28 K | 0% |
| 200 | 200 | 200 (0.34%) | 0.30 K | 0% |
| 100 | 100 | 100 (0.34%) | 0.70 K | 0% |
| 50 | 50 | 50 (0.35%) | 0.30 K | 0% |

TABLE 4

| Actual | Predicted | Predicted | Temp | |
|---|---|---|---|---|
| Rₛₕ | Global (Ω) | Final (Ω) | Error | Error |
| ∞ | 1000 | 1000 (0.69%*) | 0.21K | 0%⁺ |
| 500 | 500 | 500 (0.71%) | 0.21 K | 0% |
| 200 | 200 | 200 (0.67%) | 0.20 K | 0% |
| 100 | 100 | 100 (0.67%) | 0.34 K | 0% |
| 50 | 50 | 50 (0.69%) | 0.35 K | 0% |

Table 5 may represent constant C-rate data at 23° C. during the 50th cycle.

TABLE 5

| Actual | Predicted | Predicted | Temp | |
|---|---|---|---|---|
| Rₛₕ (Ω) | Global (Ω) | Local (Ω) | Error | Error |
| ∞ | 1000 | 1000 (0.69%*) | 0.27 K\hat{ } | 0%⁺ |
| 500 | 500 | 500 (0.65%) | 0.31 K | 0% |
| 200 | 200 | 200 (0.66%) | 0.25 K | 0% |
| 100 | 100 | 100 (0.69%) | 0.38 K | 0% |
| 50 | 50 | 50 (0.65%) | 0.24 K | 0% |

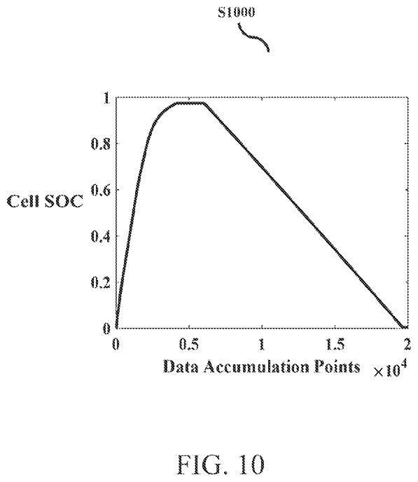

FIG. 10 is a graph S1000 illustrating an example of SFM evaluation data described according to one or more embodiments. As shown in FIG. 10, T-ROM may collect and update accurate voltage-current-SOC information with partial charge/discharge. When a parcel of charge/discharge voltage-current-SOC information is available, the voltage-current-SOC information may be collected in the background. As shown in FIG. 10, SFM evaluation data may accumulate to generate a largest possible data set for voltage-SOC for a broad SOC range. The SFM score may use the broad SOC range since the SFM score utilizes hysteresis of charge/discharge hysteresis with SOC for a short circuit system.

The SOC required for calculation may be obtained by coulomb counting ∫ₜ₂^{t1}Idt/Q. Here, I may denote a current, t may denote time, and Q may denote a rated capacity for the battery 150. When the voltage information for the broad SOC range for charge/discharge is available by accumulating it with partial charge/discharge information over multiple cycles, the data set may be ready for short resistance evaluation.

Operations, actions, blocks, steps, or the likes in the flowchart 400 may be performed in the order presented, in a different order, or simultaneously. In addition, in one or more embodiments, some of the operations, actions, blocks, steps, or the likes may be omitted, added, modified, skipped, or the like without departing from the scope of the present disclosure.

The battery management systems, processors, communicators, memories, battery management controllers, batteries, systems, electronic devices, electric vehicles, hybrid vehicles, battery management system 100, processor 110, communicator 120, memory 130, battery management controller 140, battery 150, system 2000, battery management system 100, electronic device 200, system 3000, electric vehicle 300a, hybrid vehicle 300b, and other apparatuses, units, modules, devices, and components described herein with respect to FIGS. 1-10 are implemented by or representative of hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-10 that perform the operations described in this application are performed by computing hardware, for example, by one or more processors or computers, implemented as described above executing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions in the specification, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

What is claimed is:

1. A processor-implemented method of a battery management system, the method comprising:
determining one or more pieces of sampling data from a plurality of pieces of battery usage data of a battery;
determining a first short fatigue metric (SFM) score based on the determined one or more pieces of sampling data; and
storing the first SFM score,
wherein the one or more pieces of sampling data comprises any one or any combination of any two or more of:
a high charging profile associated with the battery;
a high discharging profile associated with the battery;
a partial charging profile associated with the battery; and
a partial discharging profile associated with the battery.

2. The method of claim 1, further comprising:
determining an SFM and short circuit detection and estimation module based on the determined one or more pieces of sampling data;
determining a first resistance value using the SFM and short circuit detection and estimation module; and
determining a second SFM score based on the determined first resistance value and the determined first SFM score,
wherein the first resistance value is determined using a short circuit-reduced order model (SC-ROM) module of the SFM and short circuit detection and estimation module, and
wherein the SC-ROM module corresponds a physics-based electrochemical-thermal model comprising charge balance data of the battery to determine an effect of short circuit of the battery.

3. The method of claim 2, further comprising:
re-determining the first resistance value based on the second SFM score using the SC-ROM module;
determining a second resistance value using the SC-ROM module; and
determining an output short resistance based on the re-determined first resistance value and the determined second resistance value.

4. The method of claim 2, wherein the determining of the second SFM score comprises determining the second SFM score based on any one or any combination of any two or more of a voltage hysteresis ratio, an energy hysteresis ratio, and a charge/discharge energy hysteresis ratio.

5. The method of claim 1, wherein the first SFM score is a sum of a capacity ratio and an energy ratio of a short circuit cell of the battery.

6. The method of claim 2, wherein the second SFM score is a relative change between a sum of a capacity ratio and an energy ratio of a normal cell of the battery and the sum of the capacity ratio and the energy ratio of the short circuit cell of the battery.

7. The method of claim 2, further comprising predicting either one or both of a temperature profile associated with the battery and a voltage profile associated with the battery, based on a final short resistance.

8. The method of claim 2, wherein
the SFM and short circuit detection and estimation module determines a change of one or more parameters associated with the battery, and
the one or more parameters comprise any one or any combination of any two or more of a concentration, a state of charge, a voltage, and a temperature of the battery.

9. The method of claim 1, further comprising estimating a short circuit and a short resistance in either one or both of a cell of the battery and a battery pack of the battery, based on the determined first SFM score.

10. The method of claim 2, wherein the SFM and short circuit detection and estimation module estimates either one or both of a short circuit of the battery and a short resistance of the battery.

11. The method of claim 1, wherein the battery management system is included in any one or any combination of any two or more of a hybrid car, an electric vehicle, and an electronic device comprising the battery.

12. The method of claim 1, wherein the plurality of pieces of battery usage data comprises any one or any combination of any two or more of an initial voltage, a total current profile, current state information, and an initial temperature.

13. The method of claim 3, wherein
the first resistance value is determined by a predetermined first resolution, and
the second resistance value is determined by a resolution more precise than the first resolution around the first resistance value.

14. A non-transitory computer-readable storage medium storing instructions that, when executed by one or more processors, configure the one or more processors to perform the method of claim 1.

15. A battery management system comprising:
a battery management controller configured to:
determine one or more pieces of sampling data from a plurality of pieces of battery usage data of a battery;
determine a first short fatigue metric (SFM) score based on the determined one or more pieces of sampling data; and
store the first SFM score in the battery management system, and
wherein the one or more pieces of sampling data comprises any one or any combination of any two or more of:
a high charging profile associated with the battery;
a high discharging profile associated with the battery;
a partial charging profile associated with the battery; and
a partial discharging profile associated with the battery.

16. The battery management system of claim 15, wherein the battery management controller is further configured to:
determine an SFM and short circuit detection and estimation module based on the determined one or more pieces of sampling data,
determine a first resistance value using the SFM and short circuit detection and estimation module, and
determine a second SFM score based on the determined first resistance value and the determined first SFM score,
wherein the first resistance value is determined using a short circuit-reduced order model (SC-ROM) module of the SFM and short circuit detection and estimation module, and
wherein the SC-ROM module corresponds a physics-based electrochemical-thermal model comprising charge balance data of the battery to determine an effect of short circuit of the battery.

17. The battery management system of claim 16, wherein the battery management controller is further configured to:
re-determine the first resistance value based on the second SFM score by using the SC-ROM module;
determine a second resistance value using the SC-ROM module; and
determine an output short resistance based on the re-determined first resistance value and the determined second resistance value.

18. The battery management system of claim 15, wherein the first SFM score is a sum of a capacity ratio and an energy ratio of a short circuit cell of the battery.

19. The battery management system of claim 16, wherein the battery management controller is further configured to predict either one or both of a temperature profile associated with the battery and a voltage profile associated with the battery, based on a final short resistance.

20. The battery management system of claim 16, wherein
the SFM and short circuit detection and estimation module determines a change of one or more parameters associated with the battery, and
the one or more parameters comprise any one or any combination of any two or more of a concentration, a state of charge, a voltage, and a temperature of the battery.

21. The battery management system of claim 16, wherein the SFM and short circuit detection and estimation module estimates either one or both of a short circuit of the battery and a short resistance of the battery.

22. The battery management system of claim 15,
wherein the battery management controller comprises one or more processors, and
further comprising a memory storing instructions that, when executed by the one or more processors, configure the one or more processors to perform the determining of the one or more pieces of sampling data, the determining of the first SFM score, and the storing of the first SFM score.

23. A processor-implemented method of a battery management system, the method comprising:
determining, based on a plurality of pieces of battery usage data of a battery, one or more pieces of sampling data comprising either one or both of a charging profile and a discharging profile of the battery;
determining a first short fatigue metric (SFM) score based on the determined one or more pieces of sampling data;
determining an SFM and short circuit detection and estimation module based on the determined one or more pieces of sampling data;
determining a first resistance value using the SFM and short circuit detection and estimation module; and
determining a second SFM score based on the determined first resistance value and the determined first SFM score.
